(19) United States
(12) Patent Application Publication
(10) Pub. No.: US 2009/0061625 A1
(43) Pub. Date: Mar. 5, 2009

(54) LCD DRIVER IC AND METHOD FOR MANUFACTURING THE SAME

(75) Inventor: Byung Ho Kim, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/202,674

(22) Filed: Sep. 2, 2008

(30) Foreign Application Priority Data
Aug. 30, 2007 (KR) 10-2007-0087563

(51) Int. Cl. H01L 21/768; G09G 5/00

(52) U.S. Cl. 438/669; 345/204; 257/E21.575

(57) ABSTRACT

An LCD driver IC and a method for manufacturing the same. In one example embodiment, an LCD driver IC includes first and second main poly patterns formed separately from each other, a connection poly pattern connecting the main poly patterns, and a salicide blocking (SAB) pattern formed on the main poly patterns to block the main poly patterns.

### CROSS-REFERENCE TO A RELATED APPLICATION

This application claims the benefit of Korean Patent Application No. 10-2007-0087563, filed on Aug. 30, 2007 which is hereby incorporated by reference in its entirety as if fully set forth herein.

### BACKGROUND

1. Field of the Invention

Embodiments of the present invention relate to semiconductor devices, and more particularly to embodiments of an LCD driver IC and methods for manufacturing the same.

2. Description of the Related Art

A liquid crystal display (LCD) driver integrated circuit (IC) may be used to control several portions of an LCD panel, and several LCD driver ICs may be used in a single LCD panel. In an ordinary LCD driver IC, resistance is adjusted by varying the size of a salicide blocking (SAB) in a wide poly pattern to adjust output voltage. However, in an LCD panel using several LCD driver ICs, a block dim phenomenon may occur causing a difference in a gray level in the LCD panel due to a difference in output voltages between LCD driver ICs. This difference in output voltage may be caused by a difference in resistance ratios between the LCD driver ICs.

For example, when an SAB pattern has a larger or smaller critical dimension (CD) in a horizontal direction (X direction) than another SAB pattern, a large difference in resistance will result. The resistance of an SAB pattern is determined mainly by a non-salicide poly resistance. When the CD of a SAB pattern is changed in the X direction, a non-salicide poly area is also changed and a resistance is changed. As a result, there is a difference in resistance between LCD diver ICs, thereby causing a difference in output voltage.

Further, when an SAB pattern is shifted in a vertical direction (Y direction), the non-salicide poly area is changed and a resistance is changed, thereby causing a difference in output voltage.

### SUMMARY OF EXAMPLE EMBODIMENTS

In general, example embodiments of the invention relate to a liquid crystal display (LCD) driver integrated circuit (IC) and a method for manufacturing the same. In some example embodiments, the LCD driver IC is capable of reducing a difference in output voltage between chips.

In one example embodiment, an LCD driver IC includes first and second main poly patterns formed separately from each other, a connection poly pattern connecting the main poly patterns, and a salicide blocking (SAB) pattern formed on the main poly patterns to block the main poly patterns.

In another example embodiment, a method for manufacturing an LCD driver IC includes forming first and second main poly patterns, forming a connection poly pattern connecting the main poly patterns, and forming a salicide blocking (SAB) pattern formed on the main poly patterns to block the main poly patterns.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Aspects of example embodiments of the present invention will become apparent from the following detailed description of example embodiments given in conjunction with the accompanying drawings, in which:

FIG. 1 is a cross-sectional view of an example LCD driver IC; and

FIGS. 2 to 4 are cross-sectional views of other example LCD driver ICs similar to the example LCD driver IC of FIG. 1.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

In the following description, when a certain layer is described as being formed “on/under” another layer, the certain layer may be in direct contact with the other layer (directly) or a third layer may be interposed therebetween (indirectly).

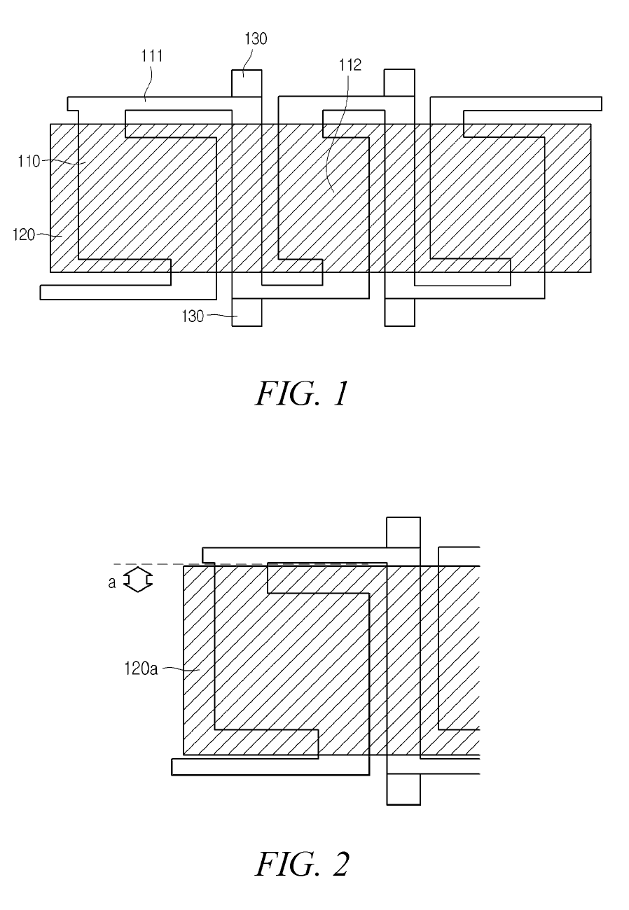

FIG. 1 is a cross-sectional view of an example LCD driver IC. As disclosed in FIG. 1, the example LCD driver IC includes a first and second main poly patterns 110 and 112 formed separately from each other, a connection poly pattern 111 connecting the main poly patterns 110 and 112, and a salicide blocking (SAB) pattern 120 formed on the main poly patterns 110 and 112. As disclosed in FIG. 1, the connection poly pattern 111 may be formed to connect an upper side of the first main poly pattern 110 to a lower side of the second main poly pattern 112. Further, contact patterns 130 may be formed at the opposite sides of the connection poly pattern 111.

As disclosed in FIG. 1, the main poly patterns 110 and 112 are designed to be separated from each other beneath the SAB pattern 120. The non-salicide main poly patterns 110 and 112 serve as resistors that are blocked by the SAB pattern 120. Also disclosed in FIG. 1, the connection poly pattern 111 is formed in a line shape. Accordingly, even when the critical dimension (CD) of the SAB pattern 120 is changed or the SAB pattern is shifted, the resistance of the example LCD driver IC is not substantially affected. This stable resistance results in a reduced difference in output voltage between LCD driver ICs within an LCD panel, thereby remarkably reducing failure. Further, repositioning the contact patterns in a vertical direction has little to no influence on a CD change of the SAB pattern 120 or a shift of the SAB pattern 120.

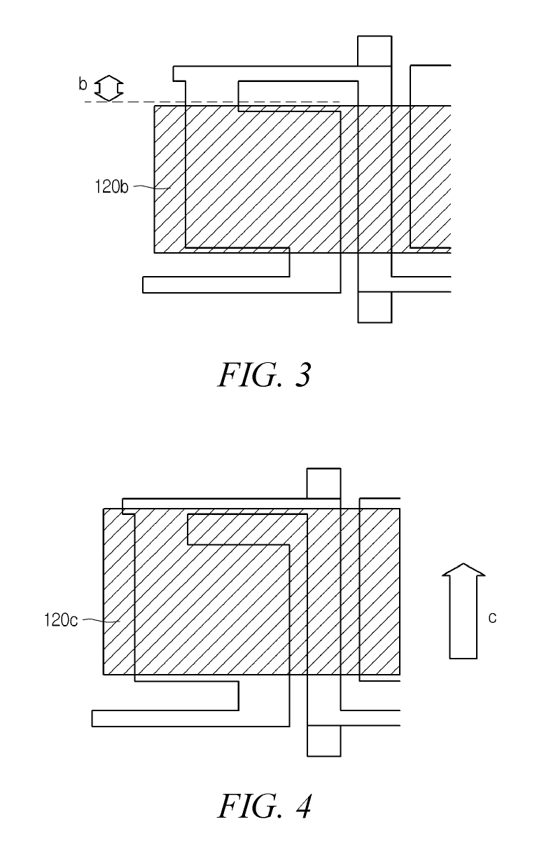

FIGS. 2 to 4 are cross-sectional views of other example LCD driver ICs similar to the example LCD driver IC of FIG. 1. With reference first to FIG. 2, an SAB pattern 120a is patterned to have a larger CD in a vertical direction (by a value ‘a’) than the SAB pattern 120 of FIG. 1. The SAB pattern 120a is formed in a horizontal direction. Accordingly, the area blocking the main poly patterns 110 and 112 is not changed and there is no change in resistance. In this case, since the SAB pattern 120a is patterned to have a larger CD in a vertical direction (by a value ‘a’), the overall blocking area of the SAB pattern 120a may be larger than the overall blocking area of the SAB pattern 120. However, the area blocking the main poly patterns 110 and 112 is not changed and the connection poly pattern 111 influenced by the CD of the SAB pattern 120a is patterned in a poly line. Thus, there is little to no change in resistance between the LCD driver IC of FIG. 2 and the LCD driver IC of FIG. 1.

With reference next to FIG. 3, an SAB pattern 120b is patterned to have a smaller CD in a vertical direction (by a value ‘b’) than the SAB pattern 120 shown in FIG. 1. The SAB pattern 120b is formed in a horizontal direction. Accordingly, an area blocking the main poly patterns 110 and 112 is not changed and there is no change in resistance. In this case, since the SAB pattern 120b is patterned to have a smaller CD in a vertical direction, the over blocking area of the SAB pattern 120a may be smaller than the overall blocking area of the SAB pattern 120. However, the area blocking the main poly patterns 110 and 112 is not changed and the connection poly pattern 111 influenced by the CD of the SAB pattern 120b is patterned in a poly line. Thus, there is little to no change in resistance between the LCD driver IC of FIG. 3 and the LCD driver IC of FIG. 1.

With reference next to FIG. 4, an SAB pattern 120c is shifted (in a direction ‘c’) compared to the SAB pattern 120 shown in FIG. 1. As the main poly patterns 110 and 112 are formed separate from each other, and the connection poly pattern 111 is formed in a line shape to compensate for the blocking area in the shift direction ‘c’, there may be no change in resistance despite the shift in the SAB pattern 120c. For example, since the upper side and the lower side of the connection poly pattern 111 are formed to have the same width, when the SAB pattern 120c is shifted, it is possible to compensate for the blocking area in the shift direction ‘c’.

An example method for manufacturing the example LCD driver IC of FIG. 1 will now be described. First, the first and second main poly patterns 110 and 112, the connection poly pattern 111, and the contact patterns 130 are formed. The main poly patterns 110 and 112, the connection poly pattern 111, and/or the contact patterns 130 may be formed at the same time or at different times. For example, after polysilicon (not shown) is formed on a substrate (not shown), the polysilicon may be etched using a specific photoresist pattern (not shown) as an etching mask to form the main poly patterns 110 and 112, the connection poly pattern 111, and the contact patterns 130. As disclosed in FIG. 1, the connection poly pattern 111 may be formed to connect the upper side of the first main poly pattern 110 and the lower side of the second main poly pattern 112. The salicide blocking (SAB) pattern 120 is next formed on the main poly patterns 110 and 112.

Although example embodiments of the present invention have been shown and described, changes might be made to these example embodiments. The scope of the invention is therefore defined in the following claims and their equivalents.

What is claimed is:

1. A liquid crystal display (LCD) driver integrated circuit (IC) comprising:
first and second main poly patterns formed separately from each other;
a connection poly pattern connecting the main poly patterns; and
a salicide blocking (SAB) pattern formed on the main poly patterns to block the main poly patterns.

2. The LCD driver IC according to claim 1, wherein the connection poly pattern is formed in a line shape to connect an upper side of the first main poly pattern to a lower side of the second main poly pattern.

3. The LCD driver IC according to claim 1, further comprising contact patterns formed at opposite sides of the connection poly pattern.

4. The LCD driver IC according to claim 2, wherein an upper portion of the connection poly pattern, connected to an upper side of the first main poly pattern, and a lower portion of the connection poly pattern, connected to a lower side of the second main poly pattern, have the same width.

5. A method for manufacturing an LCD driver IC comprising:
forming first and second main poly patterns;
forming a connection poly pattern connecting the main poly patterns; and
forming a salicide blocking (SAB) pattern formed on the main poly patterns to block the main poly patterns.

6. The method according to claim 5, wherein forming the connection poly pattern comprises forming the connection poly pattern to connect an upper side of the first main poly pattern to a lower side of the second main poly pattern.

7. The method according to claim 5, wherein forming the connection poly pattern comprises forming the connection poly pattern in a line shape to connect an upper side of the first main poly pattern to a lower side of the second main poly pattern.

8. The method according to claim 8, wherein forming the connection poly pattern comprises forming the connection poly pattern such that an upper line, connected to an upper side of the first main poly pattern, and a lower line, connected to a lower side of the second main poly pattern, have the same width.

9. The method according to claim 5, further comprising forming contact patterns at opposite sides of the connection poly pattern.

10. The method according to claim 9, wherein the contact patterns and the connection poly pattern are formed at the same time.

11. The method according to claim 5, wherein the main poly patterns and the connection poly pattern are formed at the same time.

12. The method according to claim 5, wherein forming the first and second main poly patterns and forming the connection poly pattern comprises:
forming polysilicon on a substrate;
forming a photoresist pattern on the polysilicon; and
etching the polysilicon using the photoresist pattern as an etching mask to form the first and second main poly patterns and the connection poly pattern.
